(19) United States
(12) Patent Application Publication
(10) Pub. No.: US 2026/0293251 A1
(43) Pub. Date: Sep. 24, 2026

(54) RADIATION HARDENED (RAD-HARD) DEVICES INCLUDING SUPERLATTICE TO CONTROL BORON DOPING PROFILE AND RELATED METHODS

(71) Applicant: ATOMERA INCORPORATED, LOS GATOS, CA (US)

(72) Inventors: ROBERT J. MEARS, WELLESLY, MA (US); MAREK HYTHA, BROOKLINE, MA (US); KEITH DORAN WEEKS, CHANDLER, AZ (US); NYLES WYNN CODY, TEMPE, AZ (US)

(21) Appl. No.: 19/568,009

(22) Filed: Mar. 16, 2026

Related U.S. Application Data
(60) Provisional application No. 63/773,641, filed on Mar. 18, 2025.

(51) Int. Cl. H10D 62/815; H10D 62/834; H10P 32/10; H10P 90/00; H10W 10/00; H10W 10/10

(52) U.S. Cl. CPC H10D 62/8164; H10D 62/834; H10P 32/10; H10W 10/181; H10P 90/1908; H10W 10/011

(57) ABSTRACT

A radiation-hardened (rad-hard) semiconductor device may include a boron-doped semiconductor layer, at least one superlattice within the boron-doped semiconductor layer defining first and second regions with the first region having a lower boron-10 concentration and a higher boron-11 concentration than the second region so that the first region defines an active device region being more resistant to radiation effects than the second region. The at least one superlattice may include stacked groups of layers, with each group of layers comprising stacked base semiconductor monolayers defining a base semiconductor portion, and at least one non-semiconductor monolayer constrained within a crystal lattice of adjacent base semiconductor portions.

### CROSS-REFERENCE TO RELATED APPLICATIONS

This application claims the benefit of U.S. provisional application No. 63/773,641 filed Mar. 18, 2025, which is hereby incorporated herein in its entirety by reference.

### TECHNICAL FIELD

The present disclosure generally relates to semiconductor devices, and, more particularly, to radiation hardened (rad-hard) devices and related methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si-Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region includes alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A radiation-hardened (rad-hard) semiconductor device may include a boron-doped semiconductor layer, at least one superlattice within the boron-doped semiconductor layer defining first and second regions with the first region having a lower boron-10 concentration and a higher boron-11 concentration than the second region so that the first region defines an active device region being more resistant to radiation effects than the second region. The at least one superlattice may include a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions.

In an example implementation, the boron-doped semiconductor layer may comprise a silicon-on-insulator (SOI) substrate including a buried oxide (BOX) layer, and the at least one superlattice comprises a lateral superlattice overlying the BOX layer. Furthermore, the active device region may overlie the lateral superlattice. In some embodiments, the superlattice lines at least a portion of a trench in the semiconductor layer.

By way of example, the at least one superlattice may comprise between 4 and 60 stacked groups of layers. Also by way of example, adjacent groups of layers of the superlattice may be spaced between 2 and 3 nm apart. The at least one non-semiconductor monolayer comprises oxygen, and the base semiconductor portions may comprise silicon, for example. In example implementations, the active device region may comprise at least one of a transistor body, a channel region, and a source/drain region.

A related method is for making a rad-hard semiconductor device and may include forming a boron-doped semiconductor layer and at least one superlattice within the boron-doped semiconductor layer, such as the one described briefly above. The superlattice defines first and second regions within the semiconductor layer, with the first region having a lower boron-10 concentration and a higher boron-11 concentration than the second region so that the first region defines an active device region being more resistant to radiation effects than the second region.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4 is a schematic cross-sectional view of a radiation-hardened semiconductor device including a superlattice in accordance with an example embodiment.

FIG. 5 is a schematic cross-sectional view of another embodiment of a radiation-hardened semiconductor device including a superlattice in a silicon-on-insulator (SOI) configuration in accordance with an example embodiment.

FIG. 6 is a flow diagram illustrating a method for making a radiation-hardened semiconductor device in accordance with an example embodiment.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers, and that this accordingly leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si-SiO₂ interface, reducing the presence of sub-stoichiometric SiOₓ. Alternately, the trapping of interstitials by MST layers may reduce the concentration of interstitial silicon proximate to the Si-SiO₂ interface, reducing the tendency to form sub-stoichiometric SiOₓ. Sub-stoichiometric SiOₓ at the Si-SiO₂ interface is known to exhibit inferior insulating properties relative to stoichiometric SiO₂. Reducing the amount of sub-stoichiometric SiOₓ at the interface more effectively confines free carriers (electrons or holes) in the silicon, and thus improves the mobility of these carriers due to electric fields applied parallel to the interface, as is standard practice in field effect transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as discussed further in U.S. Pat. No. 7,517,702, which is also from the present Applicant and is hereby incorporated herein in its entirety by reference.

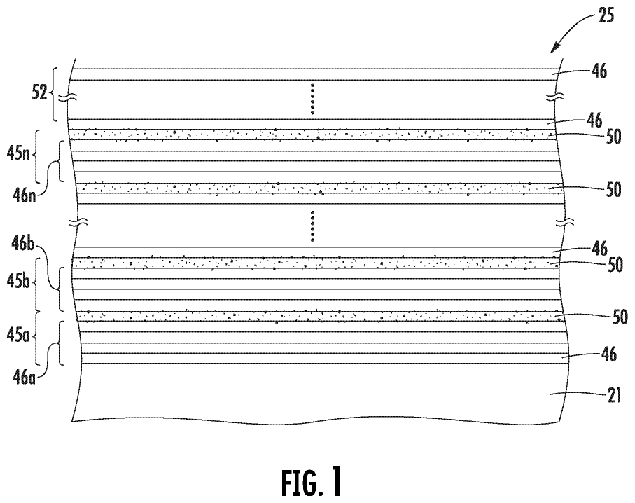

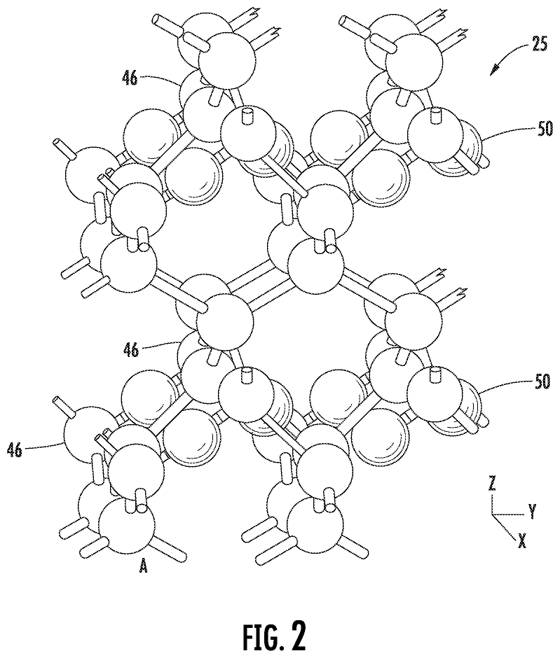

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Moreover, this superlattice structure may also advantageously act as a barrier to dopant and/or material diffusion between layers vertically above and below the superlattice 25. These properties may thus advantageously allow the superlattice 25 in one example implementation to provide an interface for high-K dielectrics which not only reduces diffusion of the high-K material into the channel region, but which may also advantageously reduce unwanted scattering effects and improve device mobility, as will be appreciated by those skilled in the art.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably, between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the invention may be readily adopted and implemented, as will be appreciated by those skilled in the art.

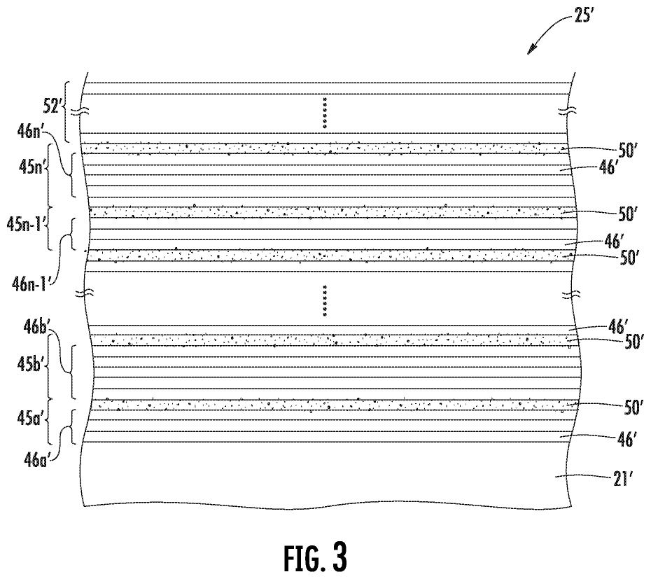

Referring now additionally to FIG. 3, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

The above-described MST films may be incorporated within various radiation hardened (rad-hard) semiconductor devices to provide significant technical advantages. By way of background, rad-hard devices are specialized electronic components designed to withstand extreme radiation environments where conventional electronics would otherwise fail. These devices may operate in challenging settings including space missions, nuclear facilities, particle accelerators, military applications, and certain medical equipment where radiation exposure occurs. Radiation causes various failures in electronics through single-event effects, total ionizing dose damage, displacement damage, and enhanced low-dose rate sensitivity, for example.

Examples of rad-hard components include specialized microprocessors and microcontrollers, radiation-resistant memory devices, hardened power management integrated circuits, specialized sensors and analog components, radiation-tolerant field-programmable gate arrays, and even radiation-resistant passive components. These components are designed using various techniques including special manufacturing processes, redundant circuits, error correction, and radiation-shielding materials to help ensure reliable operation in radiation-intense environments. The technique described herein may be used in the above-noted rad-hard devices.

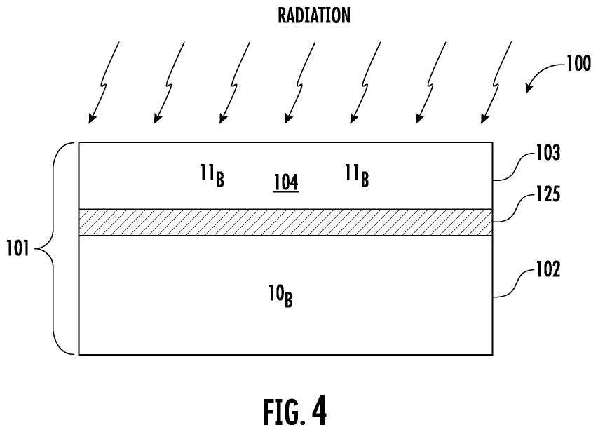

Referring now to FIG. 4, a rad-hard semiconductor device 100 in accordance with an example embodiment is now described. The semiconductor device 100 includes a semiconductor layer 101 including a substrate 102 and an epitaxial layer 103 overlying the substrate, with a superlattice 125 disposed within the semiconductor layer between the substrate and the epitaxial layer. The superlattice 125 may be configured as described above with reference to FIGS. 1-3. The substrate 102 (referenced as the second region in the claims) including a conventionally doped concentration of naturally occurring boron, including ¹⁰B, and ¹¹B as schematically indicated in FIG. 4. The epitaxial layer 103 (referenced as the first region in the claims) includes the active device region 104 therein. The active device region 104 may define at least one of a transistor body, a channel region, or a source/drain region, for example, in different embodiments. Owing to the diffusion-barrier properties of the superlattice 125, the epitaxial layer 103 has a lower ¹⁰B concentration and a higher ¹¹B concentration than the substrate 102, so that the active device region 104 is more resistant to radiation effects than the remainder of the semiconductor device 100. Stated another way, the active device region 104 has a higher concentration of boron-11 (¹¹B) than the substrate 102, as schematically indicated in FIG. 4. Radiation impinging upon the semiconductor device 100 is also illustrated schematically by the arrows shown in FIG. 4.

More particularly, naturally occurring boron exists as two primary isotopes: ¹¹B (approximately 80% natural abundance) and ¹⁰B (approximately 20% natural abundance). The isotope ¹⁰B has an anomalously high thermal neutron capture cross-section relative to most common semiconductor materials—including silicon, aluminum, nitrogen, phosphorus, oxygen, and ¹¹B itself—as illustrated by the comparative data discussed further below. Upon neutron capture, ¹⁰B emits high-energy alpha particles and lithium nuclei, creating significant ionization in the surrounding silicon. This ionization can generate electron-hole pairs within the active device region 104, potentially triggering single-event effects (SEEs) including single-event upsets (SEUs) and single-event transients (SETs). By using the superlattice 125 as a diffusion barrier, ¹⁰B introduced through conventional boron doping is substantially confined to the substrate 102, while the active device region 104 of the epitaxial layer 103 maintains a lower ¹⁰B concentration and a higher ¹¹B concentration. This reduces the number of alpha particles released upon neutron capture within the active device region 104 and thereby reduces soft-error rates. While purified ¹¹B could theoretically be used throughout the device, purifying naturally occurring boron to create a high-concentration ¹¹B supply is expensive. The present approach advantageously uses the superlattice 125 to constrain natural boron (which includes ¹⁰B) to the less-critical substrate region 102, and allows the active device region 104 to be doped with a higher concentration of ¹¹B, thus providing enhanced rad-hard protection at substantially lower cost than utilizing purified ¹¹B throughout the entire device.

The precise boron doping profile control and diffusion-barrier properties of the superlattice 125 also provide several further technical advantages for radiation hardness. With respect to charge-collection volume, radiation events deposit charge in silicon that can trigger SEEs. Wider or deeper depletion regions allow larger charge collection volumes, increasing vulnerability to such events. The superlattice 125 enables abrupt and well-defined boron doping profiles that produce sharper, shallower junction boundaries, which directly shrink the depletion-region size and reduce the volume available for radiation-induced charge collection. With fewer electrons and holes collected from radiation-generated electron-hole pairs, the occurrence of SEUs and SETs is significantly reduced.

With respect to parasitic latchup, single-event latchup (SEL) occurs due to the activation of parasitic bipolar transistors formed between wells and substrates of CMOS structures. The stable boron profiles enabled by the superlattice 125 precisely define well boundaries and reduce junction depth, limiting the resistive paths that contribute to latchup sensitivity and reducing both SEL triggering probability and SEL vulnerability. With respect to substrate noise and crosstalk, radiation-induced currents can propagate through lightly doped silicon regions of the semiconductor layer 101, causing disturbances in adjacent transistors or sensitive circuits through a charge-sharing effect.

The accurate doping placement enabled by the superlattice 125 helps reduce unintended parasitic conduction paths and reduces substrate noise sensitivity, resulting in improved isolation between sensitive circuit nodes—an advantage that is particularly significant in high-density integrated circuits. Additionally, with respect to process stability and reliability, inhibiting boron diffusion across the superlattice 125 preserves carefully engineered doping profiles during high-temperature fabrication steps. This helps ensure consistent radiation-hardening performance over the device's operational lifetime, and helps enable more accurate predictive modeling and qualification of devices for harsh radiation environments.

Furthermore, many radiation hardening by design (RHBD) techniques rely on carefully controlled doping profiles in combination with layout-level modifications such as transistor stacking, transistor folding, and well isolation. The stable doping profiles maintained by the superlattice 125 facilitate effective use of these layout-based RHBD strategies, further reducing SEE susceptibility and maximizing the effectiveness of such methods when applied in conjunction with the MST boron diffusion control described herein.

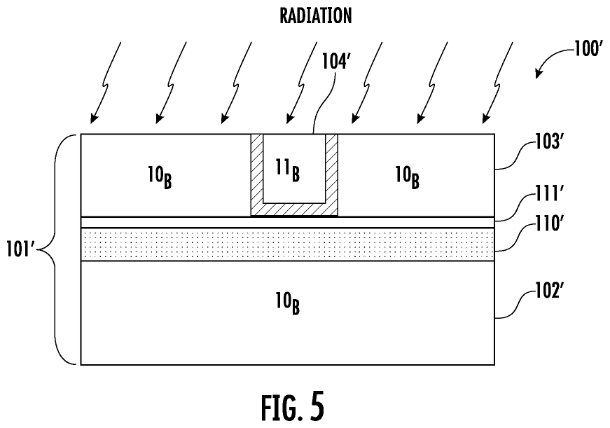

Referring now additionally to FIG. 5, another embodiment of a rad-hard semiconductor device 100′ is described. In this embodiment, the semiconductor layer 101′ illustratively includes a semiconductor or silicon-on-insulator (SOI) substrate. More particularly, the semiconductor layer 101′ includes a substrate 102′ (e.g., silicon) below a buried oxide (BOX) layer 110′, with a semiconductor seed layer 111′ overlying the BOX layer, and an epitaxial layer 103′ overlying the semiconductor seed layer. The substrate 102′ (second region in the claims) includes conventionally doped naturally occurring boron (including ¹⁰B and ¹¹B), as schematically illustrated in FIG. 5. The active device region 104′ is defined within the epitaxial layer 103′ (first region in the claims). As with the embodiment of FIG. 4, the active device region 104′ has a lower ¹⁰B concentration and a higher ¹¹B concentration than the surrounding portions of the semiconductor layer 101′, as schematically illustrated in FIG. 5. Radiation impinging upon the semiconductor device 100′ is illustrated schematically by the arrows in FIG. 5.

In this SOI embodiment, lateral and vertical superlattice 125′ portions are formed along bottom and sidewalls of a trench in the epitaxial layer 103′ just above the BOX layer 110′. The lateral superlattice 125′ portion acts as a diffusion barrier to ¹⁰B migration from the substrate 102′ upward into the active device region 104′, thereby maintaining the lower ¹⁰B concentration and a higher ¹¹B concentration in the active device region 104′ and providing the radiation-hardening advantages described above. In addition, the vertical superlattice 125′ portion formed along the trench sidewalls line at least a portion of the trench walls and further isolate the active device region 104′ from ¹⁰B migration and point-defect penetration from the surrounding regions. In this way, defects or boron redistribution occurring elsewhere in the semiconductor layer 101′ are blocked from entering the active device region 104′ (e.g., a transistor body, channel region, or source/drain region, as noted above) in a manner that would otherwise alter the dopant profile and degrade device performance and radiation hardness. The other elements of FIG. 5 not specifically mentioned are similar to those discussed above with reference to FIG. 4 and need no further discussion herein.

By way of example, the superlattice 125 or 125′ may have between 4 and 60 stacked groups of layers, with adjacent groups of layers spaced between 2 and 3 nm apart, providing an effective boron diffusion barrier while remaining compatible with standard semiconductor fabrication processes. A boron dose on the order of 1×10¹⁹ cm⁻³ may be used in example implementations. The anomalously high thermal neutron capture cross-section of ¹⁰B relative to other common semiconductor-relevant materials is illustrated by comparing the thermal neutron reaction cross-section (in barns, where one barn equals 10⁻²⁴ cm²) across a range of materials including ¹⁰B, Tungsten, Arsenic, Titanium, Copper, Nitrogen, Aluminum, Silicon, Phosphorus, Oxygen, and ¹¹B. The cross-section of ¹⁰B is orders of magnitude greater than all of the foregoing materials, including ¹¹B, confirming that controlling the concentration and location of ¹⁰B within the semiconductor device 100 through use of the superlattice 125 as a diffusion barrier provides a substantial and technically meaningful radiation-hardening benefit.

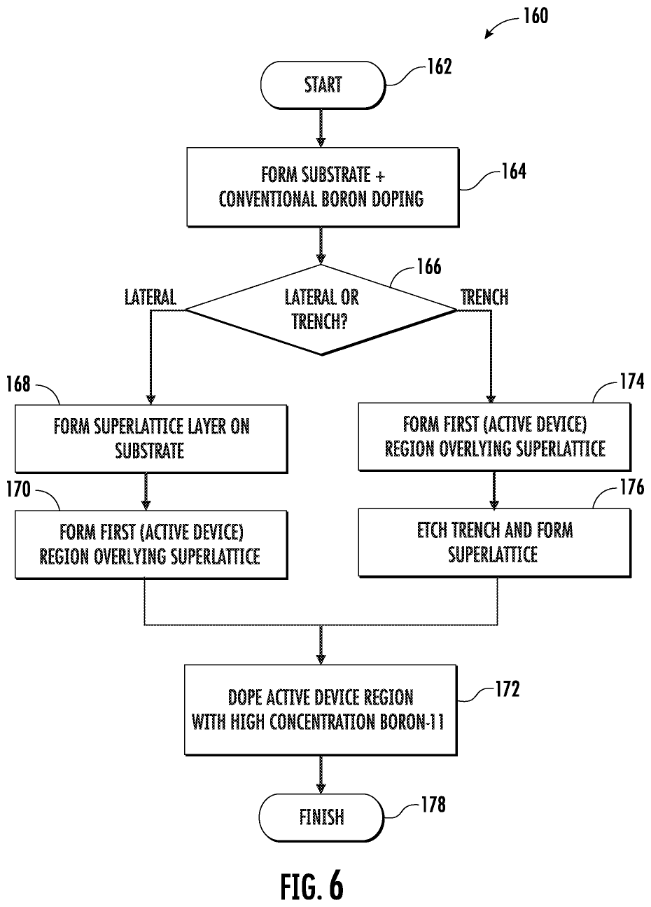

Referring now to FIG. 6, a method 160 for making a rad-hard semiconductor device in accordance with an example embodiment will now be described. Beginning at block 162, the method 160 proceeds to block 164, which includes forming a substrate with conventional boron doping—i.e., introducing naturally occurring boron containing ¹⁰B and ¹¹B to define the second region of the device. At decision block 166, if the superlattice will be formed in a lateral configuration as seen in FIG. 4, the method proceeds to block 168 and forming a superlattice layer on the substrate (for example, by blanket deposition of an MST film on the semiconductor seed layer 111′ just above the BOX layer 110′ in an SOI device, or directly on the substrate 102 in a non-SOI device). The method then proceeds to block 170, which includes forming the epitaxial layer 103 and active device region 104 overlying the superlattice 125.

Alternatively, if a trench configuration is selected (right branch from block 166), the method proceeds to block 174, which includes forming the first (active device) region overlying the substrate, and then to block 176, which includes etching a trench in the semiconductor layer 103′ and forming the superlattice 125′ to line at least a portion of the trench to vertically isolate the active device region 104'. Both branches of the method converge at block 172, which includes doping the active device region with a high concentration of ¹¹B to establish a lower ¹⁰B concentration in the first region relative to the second region. The method illustratively concludes at block 178. As a result, the device 100 or 100′ will have an active device region 104 or 104′ with a lower ¹⁰B concentration and a higher ¹¹B concentration than the substrate 103 or adjacent portions of the semiconductor layer 103′, for example, with the superlattice 125 or 125′ serving as a diffusion barrier to maintain this differential isotope concentration, and thereby provide effective radiation hardening against neutron-induced alpha-particle emission and associated SEEs.

Additional details regarding the use of MST superlattices in rad-hard devices are set forth in the co-pending application assigned attorney docket no. 6260132, also from the present Applicant, which is hereby incorporated herein in its entirety by reference.

Many modifications and other embodiments of the invention will come to the mind of one skilled in the art having the benefit of the teachings presented in the foregoing descriptions and the associated drawings. Therefore, it is understood that the present disclosure is not to be limited to the specific embodiments disclosed, and that other modifications and embodiments are intended to be included within the scope of this disclosure.

1. A radiation-hardened (rad-hard) semiconductor device comprising:
a boron-doped semiconductor layer; and
at least one superlattice within the boron-doped semiconductor layer defining first and second regions with the first region having a lower boron-10 concentration and a higher boron-11 concentration than the second region so that the first region defines an active device region being more resistant to radiation effects than the second region;
the at least one superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

2. The rad-hard semiconductor device of claim 1 wherein the boron-doped semiconductor layer comprises a silicon-on-insulator (SOI) substrate including a buried oxide (BOX) layer, and wherein the at least one superlattice comprises a lateral superlattice overlying the BOX layer.

3. The rad-hard semiconductor device of claim 2 wherein the active device region overlies the lateral superlattice.

4. The rad-hard semiconductor device of claim 1 wherein the at least one superlattice lines at least a portion of a trench in the semiconductor layer.

5. The rad-hard semiconductor device of claim 1 wherein the at least one superlattice comprises between 4 and 60 stacked groups of layers.

6. The rad-hard semiconductor device of claim 5 wherein adjacent groups of layers are spaced between 2 and 3 nm apart.

7. The rad-hard semiconductor device of claim 1 wherein the at least one non-semiconductor monolayer comprises oxygen.

8. The rad-hard semiconductor device of claim 1 wherein the base semiconductor portions comprise silicon.

9. The rad-hard semiconductor device of claim 1 wherein the active device region comprises at least one of a transistor body, a channel region, and a source/drain region.

10. A radiation-hardened (rad-hard) semiconductor device comprising:
a boron-doped silicon layer; and
at least one superlattice within the boron-doped silicon layer defining first and second regions with the first region having a lower boron-10 concentration and a higher boron-11 concentration than the second region so that the first region defines an active device region being more resistant to radiation effects than the second region;
the at least one superlattice comprising a plurality of stacked groups of layers, each group of layers comprising a plurality of stacked base silicon monolayers defining a base silicon portion, and at least one oxygen monolayer constrained within a crystal lattice of adjacent base silicon portions.

11. The rad-hard semiconductor device of claim 10 wherein the boron-doped silicon layer comprises a silicon-on-insulator (SOI) substrate including a buried oxide (BOX) layer, and wherein the at least one superlattice comprises a lateral superlattice overlying the BOX layer.

12. The rad-hard semiconductor device of claim 11 wherein the active device region overlies the lateral superlattice.

13. The rad-hard semiconductor device of claim 10 wherein the at least one superlattice lines at least a portion of a trench in the semiconductor layer.

14. A method for making a radiation-hardened (rad-hard) semiconductor device comprising:
forming a boron-doped semiconductor layer and at least one superlattice within the boron-doped semiconductor layer defining first and second regions with the first region having a lower boron-10 concentration and a higher boron-11 concentration than the second region so that the first region defines an active device region being more resistant to radiation effects than the second region;
the at least one superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

15. The method of claim 14 wherein forming the boron-doped semiconductor layer comprises forming a silicon-on-insulator (SOI) substrate including a buried oxide (BOX) layer, and wherein forming the at least one superlattice comprises forming a lateral superlattice overlying the BOX layer.

16. The method of claim 15 wherein the active device region overlies the lateral superlattice.

17. The method of claim 14 wherein forming the superlattice comprising forming the superlattice to line at least a portion of a trench in the semiconductor layer.

18. The method of claim 14 wherein the at least one non-semiconductor monolayer comprises oxygen.

19. The method of claim 14 wherein the base semiconductor portions comprise silicon, and the at least one non-semiconductor monolayer comprises oxygen.
